(19) United States
(12) Patent Application Publication
(10) Pub. No.: US 2025/0351646 A1
(43) Pub. Date: Nov. 13, 2025

(54) ASSEMBLY SUBSTRATE STRUCTURE FOR SEMICONDUCTOR LIGHT-EMITTING ELEMENT FOR DISPLAY PIXEL, AND DISPLAY DEVICE COMPRISING SAME

(71) Applicants: LG ELECTRONICS INC., Seoul (KR); LG DISPLAY CO., LTD., Seoul (KR)

(72) Inventors: Byoungkwon CHO, Seoul (KR); Wonseok CHOI, Seoul (KR); Jeonghyo KWON, Seoul (KR); Sungmin PARK, Seoul (KR); Jinhyuk JUNG, Seoul (KR)

(73) Assignees: LG ELECTRONICS INC., Seoul (KR); LG DISPLAY CO., LTD., Seoul (KR)

(21) Appl. No.: 19/099,316

(22) PCT Filed: Jul. 29, 2022
(86) PCT No.: PCT/KR2022/011247

§ 371 Date: Jan. 28, 2025

(51) Int. Cl. H10H 29/49; H01L 25/075; H10H 29/37

(52) U.S. Cl. CPC H10H 29/49; H10H 29/37; H01L 25/0753

(57) ABSTRACT

The embodiment relates to an assembly substrate structure of a semiconductor light emitting device for a display pixel and a display device including the same. The assembly substrate structure of a semiconductor light emitting device for a display pixel according to the embodiment may include a first assembly electrode and a second assembly electrode disposed to be spaced apart from each other on a substrate, an assembly partition wall disposed on the first and second assembly electrodes with a predetermined assembly hole, and a first side assembly electrode or a second side assembly electrode electrically connected to the first assembly electrode or the second assembly electrode, respectively.

### TECHNICAL FIELD

The embodiment relates to a display device including a semiconductor light emitting device. Specifically, the embodiment relates to an assembly substrate structure of a semiconductor light emitting device for a display pixel and a display device including the same.

### BACKGROUND ART

Large-area displays includes liquid crystal displays (LCDs), OLED displays, and micro-LED displays.

Micro-LED displays are displays that use micro-LEDs, semiconductor light emitting devices with a diameter or cross-sectional area of 100 μm or less, as display elements.

Micro-LED displays have excellent performance in many characteristics such as contrast ratio, response speed, color reproducibility, viewing angle, brightness, resolution, lifespan, luminous efficiency, and luminance because they use micro-LEDs, semiconductor light emitting devices, as display elements.

In particular, micro-LED displays have the advantage of being able to freely adjust the size and resolution because the screen can be separated and combined in a modular manner, and the advantage of being able to implement a flexible display.

However, since large-area micro-LED displays require millions or more micro-LEDs, there is a technical problem that makes it difficult to quickly and accurately transfer micro-LEDs to the display panel.

Transfer technologies that are being developed recently include a pick and place process, a laser lift-off method, or a self-assembly method.

Among these, the self-assembly method is a method in which semiconductor light emitting devices find their assembly positions on their own in a fluid, and is advantageous for implementing large-screen display devices.

Recently, U.S. Pat. No. 9,825,202 presented a micro-LED structure suitable for self-assembly, but research on the technology for manufacturing displays through self-assembly of micro-LEDs is still insufficient.

In particular, in the conventional technology, when rapidly transferring millions or more semiconductor light emitting devices to a large display, the transfer speed can be improved, but there is a technical problem in that the transfer error rate can increase, which lowers the transfer yield.

Meanwhile, a self-assembly transfer process using dielectrophoresis (DEP) is being attempted in related technologies, but there is a problem in that the self-assembly rate is low due to the unevenness of the DEP force.

Meanwhile, the self-assembly method using the DEP force of the internal technology includes the step of first moving the LED chip to the assembly hole area with the magnetic force of the magnet, and the step of assembling the LED chip into the assembly hole with the DEP force by applying an alternating current to the assembly wiring.

Meanwhile, the LED chip is assembled using the DEP force using a pair of corresponding first and second assembly electrodes in the internal technology, but the DEP force in the assembly hole is not strong, so there is an issue with the assembly rate of the LED chip, and also, an issue has been discovered in the internal research that among the LED chips assembled on the assembly electrode, if the DEP force is weak, LED chips are detached due to the magnetic force of the magnet.

In addition, the problem of the assembly force of the LED chip being reduced as the DEP force is concentrated in the lower area of the assembly hole in the internal technology is being studied.

### DISCLOSURE

### Technical Problem

One of the technical objects of the embodiment is to solve the problem of low self-assembly rate due to non-uniformity of DEP force in the self-assembly method using dielectrophoresis (DEP).

Another technical object of the embodiment is to solve the problem of low DEP force in the assembly hole, which causes an issue in the assembly rate of the LED chip.

Another technical object of the embodiment is to solve the problem of low DEP force in the assembly hole, which causes the LED chips assembled on the assembly electrode to be separated by the magnetic force of the magnet.

Another technical object of the embodiment is to solve the problem of low assembly force of the LED chip due to the DEP force being concentrated in the lower area of the assembly hole.

The technical objects of the embodiment are not limited to those described in this item, and include those that can be understood throughout the specification.

### Technical Solution

The assembly substrate structure of the semiconductor light emitting device for the display pixel according to the embodiment may include a first assembly electrode and a second assembly electrode that are disposed spaced apart from each other on the substrate, an assembly partition wall that is disposed on the first and second assembly electrodes and has a predetermined assembly hole, and a first side assembly electrode or a second side assembly electrode that is electrically connected to the first assembly electrode or the second assembly electrode, respectively.

The first side assembly electrode may include a first-first horizontal electrode, a first-second horizontal electrode, and a first bridge wiring that connects the first-first horizontal electrode and the first-second horizontal electrode.

The second side assembly electrode may include a second-first horizontal electrode, a second-second horizontal electrode, and a second bridge wiring that vertically connects the second-first horizontal electrode and the second-second horizontal electrode.

The embodiment may further include a side wiring that is electrically connected to the first assembly electrode or the second assembly electrode.

The upper end of the side wiring may be disposed higher than the upper end of the first side assembly electrode or the second side assembly electrode.

The embodiment may further include a light-transmitting first panel wiring disposed on the upper side of the first side assembly electrode or the second side assembly electrode and electrically connected.

The light-transmitting first panel wiring may include a first-first panel electrode electrically connected to the first side assembly electrode or the second side assembly electrode and a first-second panel electrode electrically connected to the first-first panel electrode.

The assembly substrate structure of a semiconductor light emitting device for a display pixel according to the embodiment may include a third assembly electrode disposed on the substrate, a fourth assembly electrode disposed on the upper side of the third assembly electrode, an assembly partition wall including a predetermined assembly hole and disposed on the third and fourth assembly electrodes, and a first side assembly electrode or a second side assembly electrode electrically connected to the first assembly electrode, respectively.

The first side assembly electrode may include a first-first horizontal electrode, a first-second horizontal electrode, and a first bridge wiring connecting the first-first horizontal electrode and the first-second horizontal electrode.

The third assembly electrode may be disposed spaced apart from each other with a predetermined through-space in the substrate, and the fourth assembly electrode may be disposed above the through-space of the third assembly electrode.

The third assembly electrode may include a third-first assembly electrode and a third-second assembly electrode disposed spaced apart from each other with the through-space.

The fourth assembly electrode may include a fourth-first assembly electrode disposed within the through-space of the third assembly electrode, and a fourth-second assembly electrode extending upward from the fourth-first assembly electrode and disposed above the through-space.

The fourth-first assembly electrode may be disposed at the same height as the third assembly electrode.

The fourth-second assembly electrode may be positioned at a higher position than the third assembly electrode.

In addition, a display device including a semiconductor light emitting device according to an embodiment may include an assembly substrate structure of a semiconductor light emitting device for a display pixel according to one of the embodiments.

### Advantageous Effects

According to the assembly substrate structure of a semiconductor light emitting device for a display pixel according to an embodiment and a display device including the same, there is a technical effect that can solve a problem of a low self-assembly rate due to unevenness of DEP force in a self-assembly method using dielectrophoresis (DEP) by including a first side assembly electrode (351) or a second side assembly electrode (352) electrically connected to the first assembly electrode (310) or the second assembly electrode (320), respectively.

In addition, the embodiment includes a first side assembly electrode (351) or a second side assembly electrode (352) electrically connected to the first assembly electrode (310) or the second assembly electrode (320), respectively, thereby solving the problem of an issue in the assembly rate of the LED chip due to a weak DEP force in the assembly hole, and the problem of the LED chips assembled on the assembly electrode being separated by the magnetic force of the magnet when the DEP force is weak.

For example, according to the embodiment, by including a first side assembly electrode (351) or a second side assembly electrode (352) electrically connected to the first assembly electrode (310) or the second assembly electrode (320), a second DEP force (DEP2) can be generated between the first assembly electrode (310) and the second side assembly electrode (352), and a third DEP force (DEP3) can be generated between the second assembly electrode (320) and the first side assembly electrode (351). Therefore, according to the embodiment, since a strong DEP force can be generated uniformly from the lower side to the upper side of the assembly hole (340H), there is a technical effect that can significantly improve the assembly rate and assembly speed.

In addition, for example, there is a technical effect that a semiconductor light emitting device (150N) assembled in the assembly hole can be stably fixed in the assembly hole without being detached by the magnetic force of the magnet by the strong first DEP force (DEP1) between the first assembly electrode (310) and the second assembly electrode (320).

In addition, the embodiment has a technical effect that can solve the problem of the assembly force of the LED chip being reduced due to the DEP force being concentrated in the lower region of the assembly hole by including a first side assembly electrode (351) or a second side assembly electrode (352) electrically connected to the first assembly electrode (310) or the second assembly electrode (320), respectively.

In addition, according to the embodiment, the first side assembly electrode (351) or the second side assembly electrode (352) is electrically connected to the side wiring (330), so that power can be applied to the semiconductor light emitting device (150N) to function as a pixel electrode for each pixel, which has a special technical effect. In addition, the upper end of the side wiring (330) is disposed higher than the upper end of the first side assembly electrode (351) or the second side assembly electrode (352), so that the electrical contact characteristics between the side wiring (330) and the first side assembly electrode (351) and the second side assembly electrode (352) can be improved.

In addition, according to the display device according to the second embodiment, by including a light-transmitting first panel wiring (380) electrically connected to the first side assembly electrode (351) or the second side assembly electrode (352), the panel wiring is disposed on one side above the pixel, so that the panel wiring is not located within the substrate, thereby improving the efficiency and reliability of the wiring process.

According to the third embodiment, the third assembly electrode (313) and the fourth assembly electrode (314) are disposed very close together, but are also disposed spatially apart, so that a uniform and very strong DEP force can be formed. Accordingly, the third embodiment can form a uniform and strong first DEP force (DEP1) between the third assembly electrode (313) and the fourth assembly electrode (314), thereby generating a strong DEP fixing force at the bottom of the assembly hole (340H).

For example, in the third embodiment, a strong second DEP force (DEP2) can be formed between the fourth-second assembly electrode (314b) and the second side assembly electrode (352), and a strong third DEP force (DEP3) can be formed between the fourth-second assembly electrode (314b) and the first side assembly electrode (351). Accordingly, according to the third embodiment, a second DEP force (DEP2) can be generated between the fourth assembly electrode (314) and the second side assembly electrode (352), and a third DEP force (DEP3) can be generated between the fourth assembly electrode (314) and the first side assembly electrode (351). Therefore, according to the fourth embodiment, there is a special technical effect of being able to generate a strong DEP force that is uniform from the bottom to the top of the assembly hole (340H).

The technical effects of the embodiment are not limited to those described in this item, and include those that can be understood throughout the entire specification.

### DESCRIPTION OF DRAWINGS

FIG. 1 is an example of a living room of a house in which a display device according to an embodiment is placed.

FIG. 2 is a block diagram schematically showing a display device according to an embodiment.

FIG. 3 is a circuit diagram showing an example of a pixel of FIG. 2.

FIG. 4 is an enlarged view of a first panel area in the display device of FIG. 1.

FIG. 5 is a cross-sectional view along the line B1-B2 of the A2 area of FIG. 4.

FIG. 6 is an example of a light emitting device according to an embodiment being assembled to a substrate by a self-assembly method.

FIG. 7 is a drawing showing a tilt phenomenon occurring during self-assembly of an internal technology.

FIG. 8 is a cross-sectional view of a display device (300) including a semiconductor light emitting device according to the first embodiment.

FIG. 9 is a cross-sectional view of a semiconductor light emitting device (150N) adopted in a display device (300) including a semiconductor light emitting device according to the first embodiment.

FIGS. 10A to 10D are explanatory examples of technical features in a display device (300) equipped with a semiconductor light emitting device according to an embodiment.

FIG. 11 is a cross-sectional view of an assembly substrate structure of a semiconductor light emitting device for a display pixel according to a second embodiment and a display device (302) including the same.

FIG. 12 is a cross-sectional view of a display device (303) equipped with a semiconductor light emitting device according to the third embodiment.

FIG. 13 is an explanatory example of the technical features of the third embodiment illustrated in FIG. 12.

### MODE FOR INVENTION

Hereinafter, the embodiments disclosed in the present specification will be described in detail with reference to the attached drawings. The suffixes ‘module’ and ‘part’ for components used in the following description are given or used interchangeably in consideration of the ease of writing the specification, and do not have distinct meanings or roles in themselves. In addition, the attached drawings are intended to facilitate easy understanding of the embodiments disclosed in the present specification, and the technical ideas disclosed in the present specification are not limited by the attached drawings. In addition, when an element such as a layer, region, or substrate is mentioned as existing ‘on’ another element, this includes that it may be directly on the other element or that other intermediate elements may exist between them.

The display device described in the present specification includes a digital TV, a mobile phone, a smart phone, a laptop computer, a digital broadcasting terminal, a PDA (personal digital assistant), a PMP (portable multimedia player), a navigation, a slate PC, tablet PC, an Ultra-Book, desktop computer, etc. However, the configuration according to the embodiment described in this specification can be applied to a device capable of displaying, even if it is a new product type developed in the future.

The following describes a light emitting device according to the embodiment and a display device including the same.

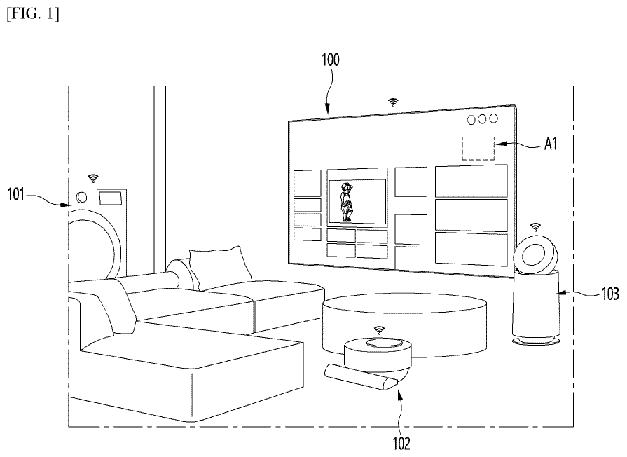

FIG. 1 illustrates a living room of a house in which a display device (100) according to the embodiment is placed.

The display device (100) of the embodiment can display the status of various electronic products such as a washing machine (101), a robot vacuum cleaner (102), and an air purifier (103), can communicate with each electronic product based on IoT, and can also control each electronic product based on the user's setting data.

The display device (100) according to the embodiment may include a flexible display manufactured on a thin and flexible substrate. The flexible display may be bent or rolled like paper while maintaining the characteristics of a conventional flat panel display.

In the flexible display, visual information may be implemented by independently controlling the light emission of unit pixels disposed in a matrix form. A unit pixel means a minimum unit for implementing one color. The unit pixel of the flexible display may be implemented by a light emitting device. In the embodiment, the light emitting device may be a Micro-LED or a Nano-LED, but is not limited thereto.

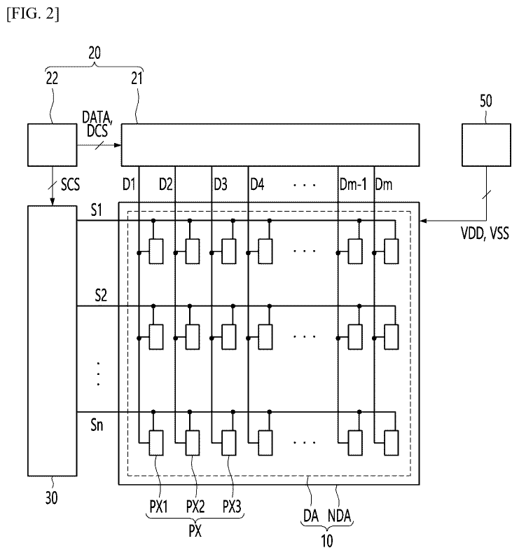

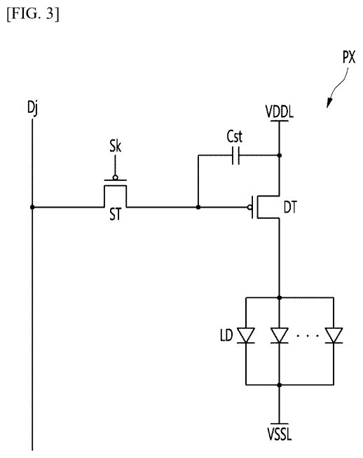

FIG. 2 is a block diagram schematically showing a display device according to the embodiment, and FIG. 3 is a circuit diagram showing an example of a pixel of FIG. 2.

Referring to FIGS. 2 and 3, the display device according to the embodiment may include a display panel (10), a driving circuit (20), a scan driving unit (30), and a power supply circuit (50).

The display device (100) of the embodiment can drive the light emitting element in an active matrix (AM) method or a passive matrix (PM) method.

The driving circuit (20) may include a data driving unit (21) and a timing control unit (22).

The display panel (10) can be divided into a display area (DA) and a non-display area (NDA) disposed around the display area (DA). The display area (DA) is an area where pixels (PX) are formed to display an image. The display panel (10) may include data lines (D1 to Dm, m is an integer greater than or equal to 2), scan lines (S1 to Sn, n is an integer greater than or equal to 2) intersecting the data lines (D1 to Dm), a high-potential voltage line to which a high-potential voltage is supplied, a low-potential voltage line to which a low-potential voltage is supplied, and pixels (PX) connected to the data lines (D1 to Dm) and the scan lines (S1 to Sn).

Each of the pixels (PX) may include a first sub-pixel (PX1), a second sub-pixel (PX2), and a third sub-pixel (PX3). The first sub-pixel (PX1) may emit a first color light of a first wavelength, the second sub-pixel (PX2) may emit a second color light of a second wavelength, and the third sub-pixel (PX3) may emit a third color light of a third wavelength. The first color light may be red light, the second color light may be green light, and the third color light may be blue light, but the present invention is not limited thereto. In addition, although FIG. 2 exemplifies that each of the pixels (PX) includes three sub-pixels, the present invention is not limited thereto. That is, each of the pixels (PX) may include four or more sub-pixels.

Each of the first sub-pixel (PX1), the second sub-pixel (PX2), and the third sub-pixel (PX3) may be connected to at least one of the data lines (D1 to Dm), at least one of the scan lines (S1 to Sn), and a high-potential voltage line. The first sub-pixel (PX1) may include light emitting devices (LD), a plurality of transistors for supplying current to the light emitting devices (LD), and at least one capacitor (Cst), as shown in FIG. 3.

Although not shown in the drawing, each of the first sub-pixel (PX1), the second sub-pixel (PX2), and the third sub-pixel (PX3) may include only one light emitting device (LD) and at least one capacitor (Cst).

Each of the light emitting devices (LD) may be a semiconductor light emitting diode including a first electrode, a plurality of conductivity type semiconductor layers, and a second electrode. Here, the first electrode may be an anode electrode, and the second electrode may be a cathode electrode, but is not limited thereto.

Referring to FIG. 3, the plurality of transistors may include a driving transistor (DT) that supplies current to the light emitting elements (LD), and a scan transistor (ST) that supplies a data voltage to the gate electrode of the driving transistor (DT). The driving transistor (DT) may include a gate electrode connected to a source electrode of the scan transistor (ST), a source electrode connected to a high-potential voltage line to which a high-potential voltage is applied, and a drain electrode connected to first electrodes of the light emitting elements (LD). The scan transistor (ST) may include a gate electrode connected to a scan line (Sk, where k is an integer satisfying 1≤k≤n), a source electrode connected to the gate electrode of the driving transistor (DT), and a drain electrode connected to a data line (Dj, where j is an integer satisfying 1≤j≤m).

A capacitor (Cst) is formed between the gate electrode and the source electrode of the driving transistor (DT). The storage capacitor (Cst) can charge a difference value between the gate voltage and the source voltage of the driving transistor (DT).

The driving transistor (DT) and the scan transistor (ST) may be formed as thin film transistors. In addition, in FIG. 3, the driving transistor (DT) and the scan transistor (ST) are described mainly as being formed as P-type MOSFETs (Metal Oxide Semiconductor Field Effect Transistors), but the present invention is not limited thereto. The driving transistor (DT) and the scan transistor (ST) may also be formed as N-type MOSFETs. In this case, the positions of the source electrode and the drain electrode of each of the driving transistor (DT) and the scan transistor (ST) can be changed.

In addition, in FIG. 3, it is exemplified that each of the first sub-pixel (PX1), the second sub-pixel (PX2), and the third sub-pixel (PX3) includes a 2T1C (2 Transistor-1 capacitor) having one driving transistor (DT), one scan transistor (ST), and one capacitor (Cst), but the present invention is not limited thereto. Each of the first sub-pixel (PX1), the second sub-pixel (PX2), and the third sub-pixel (PX3) may include a plurality of scan transistors (ST) and a plurality of capacitors (Cst).

Referring again to FIG. 2, the driving circuit (20) outputs signals and voltages for driving the display panel (10). To this end, the driving circuit (20) may include a data driving unit (21) and a timing control unit (22).

The data driving unit (21) receives digital video data (DATA) and a source control signal (DCS) from the timing control unit (22). The data driving unit (21) converts digital video data (DATA) into analog data voltages according to the source control signal (DCS) and supplies the data lines (D1 to Dm) of the display panel (10).

The timing control unit (22) receives digital video data (DATA) and timing signals from the host system. The timing signals may include a vertical sync signal, a horizontal sync signal, a data enable signal, and a dot clock. The host system may be an application processor of a smartphone or tablet PC, a monitor, a system on chip of a TV, etc.

The scan driving unit (30) receives a scan control signal (SCS) from the timing control unit (22). The scan driver (30) generates scan signals according to a scan control signal (SCS) and supplies them to the scan lines (S1 to Sn) of the display panel (10). The scan driver (30) may include a plurality of transistors and may be formed in a non-display area (NDA) of the display panel (10). Alternatively, the scan driver (30) may be formed as an integrated circuit, in which case it may be mounted on a gate flexible film attached to the other side of the display panel (10).

The power supply circuit (50) may generate a high-potential voltage (VDD) and a low-potential voltage (VSS) for driving the light emitting devices (LD) of the display panel (10) from the main power supply and supply them to the high-potential voltage line and the low-potential voltage line of the display panel (10). In addition, the power supply circuit (50) may generate and supply driving voltages for driving the driving circuit (20) and the scan driver (30) from the main power supply.

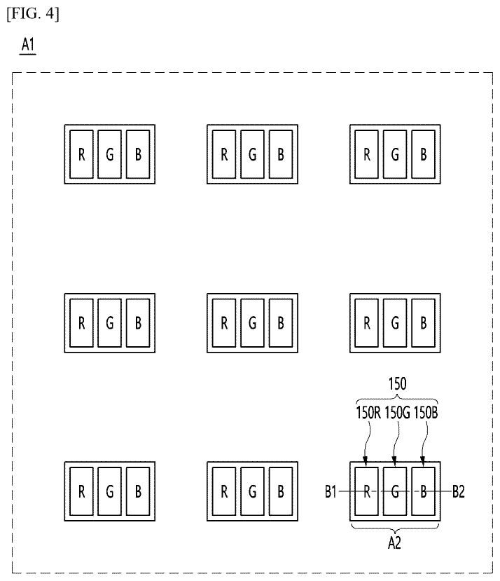

FIG. 4 is an enlarged view of the first panel area (A1) in the display device of FIG. 1.

According to FIG. 4, the display device (100) of the embodiment can be manufactured by mechanically and electrically connecting a plurality of panel areas such as the first panel area (A1) by tiling.

The first panel area (A1) may include a plurality of light emitting devices (150) disposed for each unit pixel (PX of FIG. 2).

For example, the unit pixel (PX) may include a first sub-pixel (PX1), a second sub-pixel (PX2), and a third sub-pixel (PX3). For example, a plurality of red light emitting devices (150R) can be disposed in the first sub-pixel (PX1), a plurality of green light emitting devices (150G) can be disposed in the second sub-pixel (PX2), and a plurality of blue light emitting devices (150B) can be disposed in the third sub-pixel (PX3). The unit pixel (PX) may further include a fourth sub-pixel in which no light emitting device is disposed, but is not limited thereto. Meanwhile, the light emitting device (150) may be a semiconductor light emitting device.

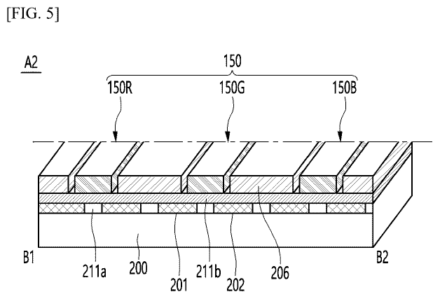

Next, FIG. 5 is a cross-sectional view taken along the line B1-B2 of the A2 region of FIG. 4.

Referring to FIG. 5, the display device (100) of the embodiment may include a substrate (200), assembly wiring (201, 202), a first insulating layer (211a), a second insulating layer (211b), a third insulating layer (206), and a plurality of light emitting devices (150).

The assembly wiring may include a first assembly wiring (201) and a second assembly wiring (202) that are spaced apart from each other. The first assembly wiring (201) and the second assembly wiring (202) may be provided to generate a dielectrophoretic force to assemble the light emitting device (150). In addition, the first assembly wiring (201) and the second assembly wiring (202) may be electrically connected to the electrodes of the light emitting device and may function as electrodes of the display panel.

The assembly wiring (201, 202) may be formed of a light-transmitting electrode (ITO) or may include a metal material having excellent electrical conductivity. For example, the assembly wiring (201, 202) may be formed of at least one of titanium (Ti), chromium (Cr), nickel (Ni), aluminum (Al), platinum (Pt), gold (Au), tungsten (W), and molybdenum (Mo), or an alloy thereof.

A first insulating layer (211a) may be disposed between the first assembly wiring (201) and the second assembly wiring (202), and a second insulating layer (211b) may be disposed on the first assembly wiring (201) and the second assembly wiring (202). The above first insulating layer (211a) and the above second insulating layer (211b) may be an oxide film, a nitride film, etc., but are not limited thereto.

The light emitting device (150) may include a red light emitting device (150), a green light emitting device (150G), and a blue light emitting device (150B0) to form a unit pixel (sub-pixel), but is not limited thereto, and may include a red fluorescent substance and a green fluorescent substance to implement red and green, respectively.

The substrate (200) may be formed of glass or polyimide. In addition, the substrate (200) may include a flexible material such as PEN (Polyethylene Naphthalate) or PET (Polyethylene Terephthalate). In addition, the substrate (200) may be a light-transmitting material, but is not limited thereto.

The third insulating layer (206) may include an insulating and flexible material such as polyimide, PEN, PET, etc., and may be formed integrally with the substrate (200) to form a single substrate.

The third insulating layer (206) may be a conductive adhesive layer having adhesiveness and conductivity, and the conductive adhesive layer may be flexible to enable a flexible function of the display device. For example, the third insulating layer (206) may be a conductive adhesive layer such as an anisotropic conductive film (ACF) or an anisotropic conductive medium, a solution containing conductive particles, etc. The conductive adhesive layer may be a layer that is electrically conductive in a vertical direction relative to the thickness, but electrically insulating in a horizontal direction relative to the thickness.

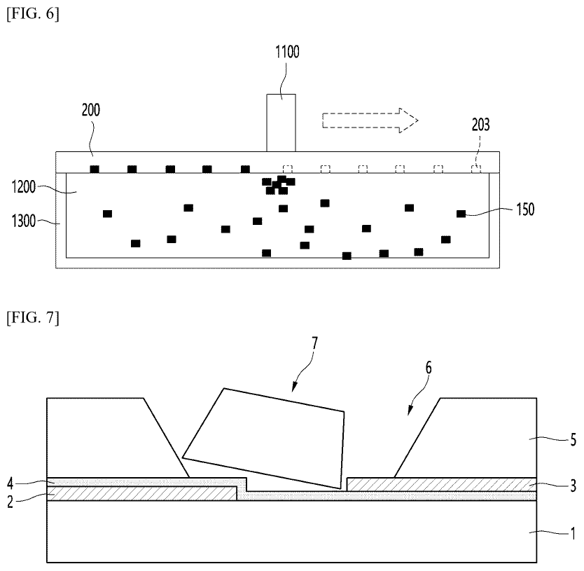

The third insulating layer (206) may include an assembly hole (203) for inserting a light emitting device (150) (see FIG. 6). Therefore, when self-assembling, the light emitting device (150) may be easily inserted into the assembly hole (203) of the third insulating layer (206). The assembly hole (203) may be called an insertion hole, a fixing hole, an alignment hole, etc.

Between the assembly wirings (201, 202), the gap is formed smaller than the width of the light emitting device (150) and the width of the assembly hole (203), so that the assembly position of the light emitting device (150) can be more precisely fixed using an electric field.

A third insulating layer (206) is formed on the assembly wiring (201, 202), so as to protect the assembly wiring (201, 202) from the fluid (1200) and prevent leakage of current flowing through the assembly wiring (201, 202). The third insulating layer (206) can be formed as a single layer or multiple layers of an inorganic insulator such as silica or alumina or an organic insulator.

In addition, the third insulating layer (206) may include an insulating and flexible material such as polyimide, PEN, PET, etc., and can be formed integrally with the substrate (200) to form a single substrate.

The third insulating layer (206) may be an adhesive insulating layer or a conductive adhesive layer having conductivity. The third insulating layer (206) may be flexible to enable a flexible function of the display device.

The third insulating layer (206) may have a partition wall, and an assembly hole (203) may be formed by the partition wall. For example, when forming the substrate (200), a part of the third insulating layer (206) may be removed, so that each of the light emitting devices (150) may be assembled into the assembly hole (203) of the third insulating layer (206).

An assembly hole (203) in which the light emitting devices (150) are coupled is formed in the substrate (200), and a surface on which the assembly hole (203) is formed may be in contact with a fluid (1200). The assembly hole (203) may guide the exact assembly position of the light emitting devices (150).

Meanwhile, the assembly hole (203) may have a shape and size corresponding to the shape of the light emitting element (150) to be assembled at the corresponding position. Accordingly, it is possible to prevent another light emitting element from being assembled in the assembly hole (203) or multiple light emitting elements from being assembled.

FIG. 6 is a drawing showing an example in which a light emitting device according to an embodiment is assembled on a substrate by a self-assembly method, and the self-assembly method of the light emitting device is described with reference to the drawings.

The substrate (200) may be a panel substrate of a display device. In the following description, the substrate (200) is described as a panel substrate of a display device, but the embodiment is not limited thereto.

Referring to FIG. 6, a plurality of light emitting devices (150) may be introduced into a chamber (1300) filled with a fluid (1200). The fluid (1200) may be water such as ultrapure water, but is not limited thereto. The chamber may be called a tank, a container, a vessel, etc.

After this, the substrate (200) may be placed on the chamber (1300). According to an embodiment, the substrate (200) may be introduced into the chamber (1300).

As shown in FIG. 5, a pair of assembly wirings (201, 202) corresponding to each light emitting device (150) to be assembled may be placed on the substrate (200).

Referring to FIG. 6, after the substrate (200) is placed, an assembly device (1100) including a magnetic body may move along the substrate (200). For example, a magnet or an electromagnet may be used as the magnetic body. The assembly device (1100) may move in contact with the substrate (200) to maximize the area to which the magnetic field is applied into the fluid (1200). According to an embodiment, the assembly device (1100) may include a plurality of magnetic bodies or may include magnetic bodies of a size corresponding to the substrate (200). In this case, the movement distance of the assembly device (1100) may be limited within a predetermined range.

The light emitting device (150) in the chamber (1300) may move toward the assembly device (1100) by the magnetic field generated by the assembly device (1100).

While the light emitting device (150) moves toward the assembly device (1100), the light emitting device may enter the assembly hole (203) by the dielectrophoretic force (DEP force) and come into contact with the substrate (200).

Specifically, the assembly wiring (201, 202) forms an electric field by the power supplied from the outside, and the dielectrophoretic force may be formed between the assembly wiring (201, 202) by the electric field. By this dielectric force, the light emitting element (150) can be fixed to the assembly hole (203) on the substrate (200).

The light emitting element (150) in contact with the substrate (200) can be prevented from being detached by the movement of the assembly device (1100) by the electric field applied by the assembly wiring (201, 202) formed on the substrate (200). According to the embodiment, by the self-assembly method using the above-described electromagnetic field, the time required for each of the light emitting elements (150) to be assembled on the substrate (200) can be drastically shortened, so that a large-area, high-pixel display can be implemented more quickly and economically.

At this time, a predetermined solder layer (not shown) is formed between the light emitting element (150) assembled on the assembly hole (203) of the substrate (200) and the assembly electrode, thereby improving the bonding strength of the light emitting element (150).

Next, a molding layer (not shown) may be formed in the assembly hole (203) of the substrate (200). The molding layer may be a transparent resin or a resin containing a reflective material or a scattering material.

FIG. 7 is a drawing showing a tilt phenomenon that occurs during self-assembly using internal technology.

According to the internal technology, a dielectric layer (4) is placed on the assembly electrodes (2, 3) on the assembly substrate (1), and self-assembly is performed by the dielectrophoretic force of the light emitting device (7) in the assembly hole (7) set by the assembly partition (5). However, according to the internal technology, the dielectrophoretic force is dispersed or weakened, so that self-assembly is not performed properly and the problem of tilting within the assembly hole (7) has been studied.

Accordingly, one of the technical objects of the embodiment is to solve the problem of low self-assembly rate due to non-uniformity of the DEP force in the self-assembly method using dielectrophoresis (DEP).

In addition, one of the technical objects of the embodiment is to solve the problem that the DEP force in the assembly hole is not strong, causing an issue in the assembly rate of the LED chip, and the problem that the LED chips assembled on the assembly electrode are separated by the magnetic force of the magnet when the DEP force is weak.

In addition, one of the technical objects of the embodiment is to solve the problem that the assembly force of the LED chip is reduced because the DEP force is concentrated in the lower area of the assembly hole.

Hereinafter, a semiconductor light emitting device display device according to an embodiment for solving the technical object will be described with reference to the drawings.

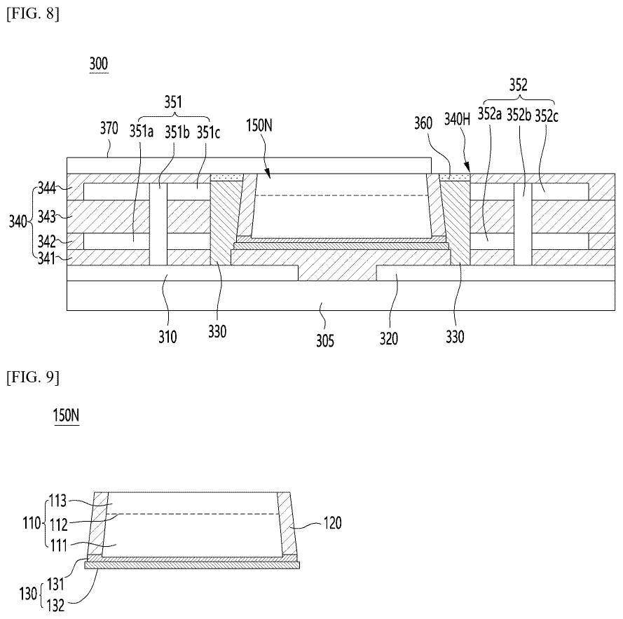

FIG. 8 is a cross-sectional view of a display device (300) including a semiconductor light emitting device according to the first embodiment, and FIG. 9 is a cross-sectional view of a semiconductor light emitting device (150N) adopted in a display device (300) including a semiconductor light emitting device according to the first embodiment. (In the following description, ‘first embodiment’ may be abbreviated as ‘embodiment’)

Referring to FIG. 8, a display device (300) having a semiconductor light emitting device according to an embodiment may include a substrate (305), a first assembly electrode (310), a second assembly electrode (320), an assembly partition (340), and a semiconductor light emitting device (150N).

Specifically, a display device (300) having a semiconductor light emitting device according to an embodiment may include a substrate (305), a first assembly electrode (310), a second assembly electrode (320) that are spaced apart from each other on the substrate (305), and a predetermined assembly hole (340H), and an assembly partition (340) that is disposed on the first and second assembly electrodes (310, 320), and a semiconductor light emitting device (150N) that is disposed within the assembly hole (340H).

In the embodiment, the first assembly electrode (310) or the second assembly electrode (320) may function as a pixel electrode in the panel.

Accordingly, the semiconductor light emitting device (150N) may be electrically connected to the first assembly electrode (310) or the second assembly electrode (320), but is not limited thereto.

For example, the embodiment may further include a side wiring (330) electrically connecting the first assembly electrode (310) or the second assembly electrode (320) and the semiconductor light emitting device (150N), but is not limited thereto.

In addition, the embodiment may include a light-transmitting resin (360) filling the assembly hole (340H) and a second panel wiring (370) electrically connected to the semiconductor light emitting device (150N).

The second panel wiring (370) may be formed of a transparent electrode and may function as a common wiring for each pixel, but is not limited thereto.

For example, the second panel wiring (370) may be formed by including at least one of a light-transmitting member, such as ITO (indium tin oxide), IAZO (indium aluminum zinc oxide), IZO (indium zinc oxide), IZTO (indium zinc tin oxide), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), and IGZO (In—Ga ZnO), but is not limited thereto.

In addition, the second panel wiring (370) may include an ohmic metal layer.

The semiconductor light emitting device (150N) according to the embodiment will be described with reference to FIG. 9 for a moment.

Referring to FIG. 9, the semiconductor light emitting device (150N) according to the embodiment can be implemented as a vertical semiconductor light emitting device as shown, but is not limited thereto, and a horizontal light emitting device can be adopted.

The semiconductor light emitting device (150N) may include a light emitting structure (110), a second electrode layer (130), and a passivation layer (120).

For example, the semiconductor light emitting device (150N) may include a second electrode layer (130) disposed on the light emitting structure (110) and a passivation layer (120) disposed on a portion of the upper surface and side surface of the light emitting structure (110).

In addition, the semiconductor light emitting device (150N) may further include a first electrode layer (not shown) on the upper surface of the light emitting structure (110), but is not limited thereto.

The light emitting structure (110) may include a first conductivity type semiconductor layer (111), a second conductivity type semiconductor layer (113), and an active layer (112) disposed therebetween. The first conductivity type semiconductor layer (111) may be an n-type semiconductor layer, and the second conductivity type semiconductor layer (113) may be a p-type semiconductor layer, but is not limited thereto.

The first conductivity type semiconductor layer (111), the active layer (112), and the second conductivity type semiconductor layer (113) may be formed of a compound semiconductor material. For example, the compound semiconductor material may be a group III-V compound semiconductor material, a group II-VI compound material, etc. For example, the compound semiconductor material may include GaN, InGaN, AlN, AlInN, AlGaN, AlInGaN, InP, GaAs, GaP, GaInP, etc.

For example, the first conductivity type semiconductor layer (111) may include a first conductive dopant, and the second conductivity type semiconductor layer (113) may include a second conductive dopant. For example, the first conductive dopant may be an n-type dopant such as silicon (Si), and the second conductive dopant may be a p-type dopant such as boron (B).

The active layer (112) is a region that generates light and may generate light having a specific wavelength band depending on the material properties of the compound semiconductor. That is, the wavelength band can be determined by the energy band gap of the compound semiconductor included in the active layer (112). Accordingly, the semiconductor light emitting element (110) of the embodiment may generate UV light, blue light, green light, and red light depending on the energy band gap of the compound semiconductor included in the active layer (112).

Next, the second electrode layer (130) may include a metal having excellent electrical conductivity. The second electrode layer (130) may include a bonding metal layer (132). For example, the second electrode layer (130) may include a bonding metal layer (132) such as Sn or In, but is not limited thereto. In addition, the second electrode layer (130) may further include an adhesive layer (not shown) such as Cr or Ti to strengthen the adhesive strength.

In addition, the second electrode layer (130) may be provided with a magnetic layer (131). The magnetic layer (131) may be provided on the lower or upper side of the light emitting structure (110). The magnetic layer (131) above may include one of nickel, cobalt, iron or neodymium magnets.

Next, the passivation layer (120) may be formed by an inorganic insulator such as silica or alumina through PECVD, LPCVD, sputtering deposition, etc. After the semiconductor light emitting device (150N) is assembled on the assembly substrate (200), a portion of the upper layer of the passivation layer (120) may be etched during the manufacturing process of the display device.

Referring back to FIG. 8, the embodiment may include a first side assembly electrode (351) or a second side assembly electrode (352) electrically connected to the first assembly electrode (310) or the second assembly electrode (320), respectively.

One of the technical objects of the embodiment is to solve the problem of low self-assembly rate due to non-uniformity of DEP force in the self-assembly method using dielectrophoresis (DEP).

Another technical object of the embodiment is to solve the problem of low self-assembly rate due to non-uniformity of DEP force in the assembly hole and the problem of detachment due to magnetic force of magnet among LED chips assembled on the assembly electrode when DEP force is weak.

Another technical object of the embodiment is to solve the problem of low assembly force of LED chips due to DEP force being concentrated in the lower area of the assembly hole.

An embodiment for solving the above technical object can solve the problem of low self-assembly rate due to non-uniformity of DEP force in a self-assembly method using dielectrophoresis (DEP) by including a first side assembly electrode (351) or a second side assembly electrode (352) electrically connected to the first assembly electrode (310) or the second assembly electrode (320), respectively.

In addition, the embodiment can solve the problem of low DEP force in the assembly hole, causing an issue in the assembly rate of the LED chip, and the problem of detachment due to the magnetic force of the magnet when the DEP force is weak among the LED chips assembled on the assembly electrode.

In addition, the embodiment can solve the problem of the assembly force of the LED chip being reduced due to the DEP force being concentrated in the lower region of the assembly hole by including a first side assembly electrode (351) or a second side assembly electrode (352) electrically connected to the first assembly electrode (310) or the second assembly electrode (320), respectively.

Specifically, the first side assembly electrode (351) may include a first-first horizontal electrode (351a), a first-second horizontal electrode (351c), and a first bridge wiring (351b) that vertically connects the first-first horizontal electrode (351a) and the first-second horizontal electrode (351c).

In addition, the second side assembly electrode (352) may include a second-first horizontal electrode (352a), a second-second horizontal electrode (352c), and a second bridge wiring (352b) that vertically connects the second-first horizontal electrode (352a) and the second-second horizontal electrode (352c).

In an embodiment, the assembly barrier wall (340) may include a first interlayer insulating layer (341) to a fourth interlayer insulating layer (341, 342, 343, 344). The assembly barrier wall (340) may be formed of an organic or inorganic insulating layer material.

The first interlayer insulating layer (341) may be formed on the first assembly electrode (310) and the second assembly electrode (320). The first-first horizontal electrode (351a) and the second-first horizontal electrode (352a) may be formed on the second interlayer insulating layer (342). The first-second horizontal electrode (351c) and the second-second horizontal electrode (352c) may be formed on the fourth interlayer insulating layer (344). The first bridge wiring (351b) and the second bridge wiring (352b) may penetrate the first to third interlayer insulating layers (341, 342, 343).

In the embodiment, the first side assembly electrode (351) or the second side assembly electrode (352) may function as an assembly electrode in self-assembly using DEP, and may also function as a pixel electrode for each pixel in the panel after assembly. There is a technical feature.

For example, the first side assembly electrode (351) or the second side assembly electrode (352) is electrically connected to the side wiring, thereby providing a special technical effect of applying power to the semiconductor light emitting device (150N) to function as a pixel electrode for each pixel.

The upper end of the side wiring (330) is disposed higher than the upper end of the first side assembly electrode (351) or the second side assembly electrode (352), thereby improving the electrical contact characteristics between the side wiring (330) and the first side assembly electrode (351) or the second side assembly electrode (352).

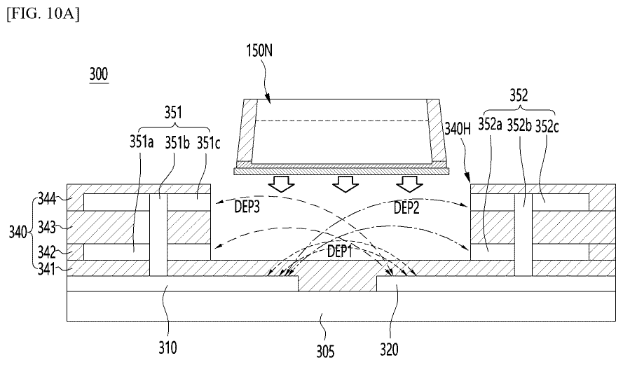

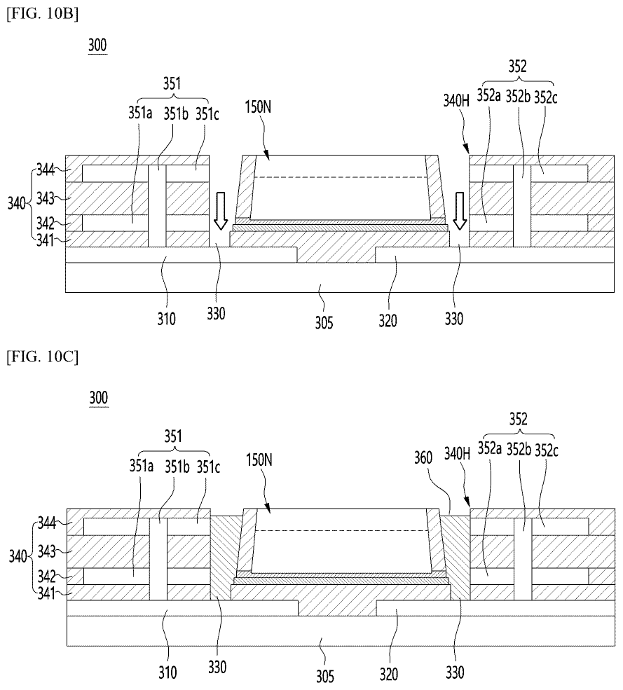

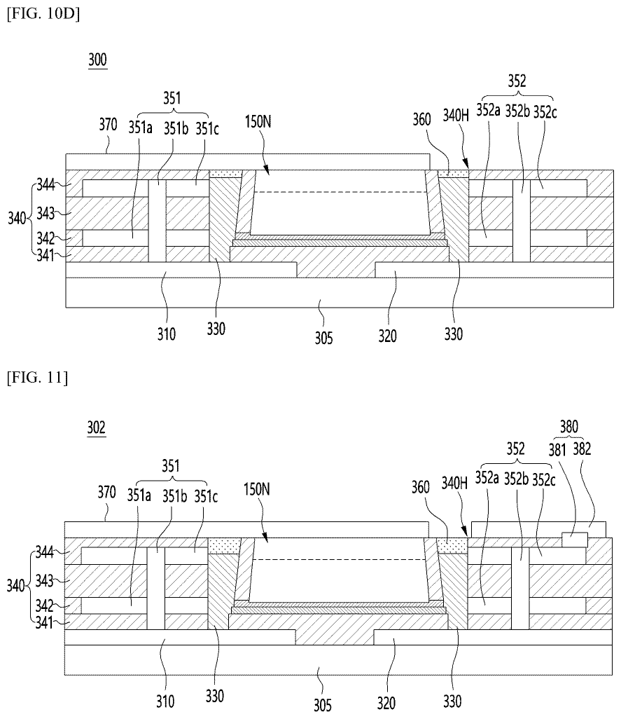

Hereinafter, the technical features of the display device (300) including the semiconductor light emitting device according to the embodiment will be described in detail with reference to FIGS. 10A to 10D.

Referring to FIG. 10A, the embodiment may include a first side assembly electrode (351) or a second side assembly electrode (352) electrically connected to the first assembly electrode (310) or the second assembly electrode (320), respectively.

In the embodiment, the first side assembly electrode (351) or the second side assembly electrode (352) may function as an assembly electrode in self-assembly using DEP, and may also function as a pixel electrode for each pixel in the panel after assembly.

Specifically, the first side assembly electrode (351) may include a first-first horizontal electrode (351a), a first-second horizontal electrode (351c), and a first bridge wiring (351b) that vertically connects the first-first horizontal electrode (351a) and the first-second horizontal electrode (351c).

In addition, the second side assembly electrode (352) may include a second-first horizontal electrode (352a), a second-second horizontal electrode (352c), and a second bridge wiring (352b) that vertically connects the second-first horizontal electrode (352a) and the second-second horizontal electrode (352c).

First, when AC power is applied, a first DEP force (DEP1) is formed between the first assembly electrode (310) and the second assembly electrode (320), thereby generating a strong DEP fixing force at the lower side of the assembly hole (340H).

In particular, a second DEP force (DEP2) may be formed between the first assembly electrode (310) and the second side assembly electrode (352). In addition, a third DEP force (DEP3) may be formed between the second assembly electrode (320) and the first side assembly electrode (351).

Accordingly, according to the embodiment, a second DEP force (DEP2) can be generated between the first assembly electrode (310) and the second side assembly electrode (352) to which power of different polarities is applied, and a third DEP force (DEP3) can be generated between the second assembly electrode (320) and the first side assembly electrode (351). Therefore, according to the embodiment, there is a special technical effect of being able to generate a uniform and strong DEP force from the bottom to the top of the assembly hole (340H).

Accordingly, according to the embodiment, by including the first side assembly electrode (351) or the second side assembly electrode (352) electrically connected to the first assembly electrode (310) or the second assembly electrode (320), respectively, a second DEP force (DEP2) can be generated between the first assembly electrode (310) and the second side assembly electrode (352), and a third DEP force (DEP3) can be generated between the second assembly electrode (320) and the first side assembly electrode (351). Therefore, according to the embodiment, since a uniform and strong DEP force can be generated from the lower side to the upper side of the assembly hole (340H), there is a technical effect of significantly improving the assembly rate and assembly speed.

Also, referring to FIG. 10B, there is a technical effect that the semiconductor light emitting device (150N) assembled in the assembly hole can be stably fixed in the assembly hole without being detached by the magnetic force of the magnet due to the strong first DEP force (DEP1) between the first assembly electrode (310) and the second assembly electrode (320).

Referring to FIG. 10B, after the semiconductor light emitting device (150N) is assembled, a part of the first interlayer insulating layer (341) can be removed to expose the upper portions of the first assembly electrode (310) and the second assembly electrode (320).

Referring to FIG. 10C next, the embodiment can form a side wiring (330) that electrically connects the first assembly electrode (310), the second assembly electrode (320), and the semiconductor light emitting device (150N).

Accordingly, according to the embodiment, the first side assembly electrode (351) or the second side assembly electrode (352) is electrically connected to the side wiring (330), thereby providing a special technical effect of being able to function as a pixel electrode for each pixel by applying power to the semiconductor light emitting device (150N).

The upper end of the side wiring (330) is positioned higher than the upper end of the first side assembly electrode (351) or the second side assembly electrode (352), thereby improving the electrical contact characteristics between the side wiring (330) and the first side assembly electrode (351) or the second side assembly electrode (352).

Next, referring to FIG. 10D, a light-transmitting resin (360) filling the assembly hole (340H) and a second panel wiring (370) electrically connected to the semiconductor light emitting device (150N) can be formed. The second panel wiring (370) can be formed as a transparent electrode and can function as a common wiring for each pixel, but is not limited thereto.

Through this, the assembly substrate structure of the semiconductor light emitting device for the display pixel according to the first embodiment and the display device including the same can be completed.

According to the embodiment, by including the first side assembly electrode (351) or the second side assembly electrode (352) electrically connected to the first assembly electrode (310) or the second assembly electrode (320), respectively, there is a technical effect that can solve the problem of the assembly rate of the LED chip being low due to the DEP force in the assembly hole being weak, and the problem of the LED chips assembled on the assembly electrode being separated by the magnetic force of the magnet when the DEP force is weak.

In addition, the embodiment has a technical effect that can solve the problem of the assembly force of the LED chip being reduced due to the DEP force being concentrated in the lower region of the assembly hole by including the first side assembly electrode (351) or the second side assembly electrode (352) electrically connected to the first assembly electrode (310) or the second assembly electrode (320), respectively.

In addition, according to the embodiment, the first side assembly electrode (351) or the second side assembly electrode (352) is electrically connected to the side wiring (330), thereby providing a special technical effect of applying power to the semiconductor light emitting device (150N) to function as a pixel electrode for each pixel.

Next, FIG. 11 is a cross-sectional view of an assembly substrate structure of a semiconductor light emitting device for a display pixel according to the second embodiment and a display device (302) including the same.

The second embodiment may adopt the technical features of the first embodiment, and the main features of the second embodiment will be described below.

The display device (302) according to the second embodiment may include a light-transmitting first panel wiring (380) electrically connected to the first side assembly electrode (351) or the second side assembly electrode (352).

For example, the second embodiment may include a light-transmitting first panel wiring (380) electrically connected to the second side assembly electrode (352) and disposed on the second side assembly electrode (352).

For example, the first panel wiring (380) may include a light-transmitting member, such as ITO, that transmits light.

The light-transmitting first panel wiring (380) may include a first-first panel electrode (381) electrically connected to the second side assembly electrode (352) and a first-second panel electrode (382) electrically connected to the first-first panel electrode (381).

According to the display device (302) equipped with a semiconductor light emitting device according to the second embodiment, by including a light-transmitting first panel wiring (380) electrically connected to the first side assembly electrode (351) or the second side assembly electrode (352), the panel wiring is disposed on one side above the pixel, so that the panel wiring is not located within the substrate, thereby improving the efficiency and reliability of the wiring process.

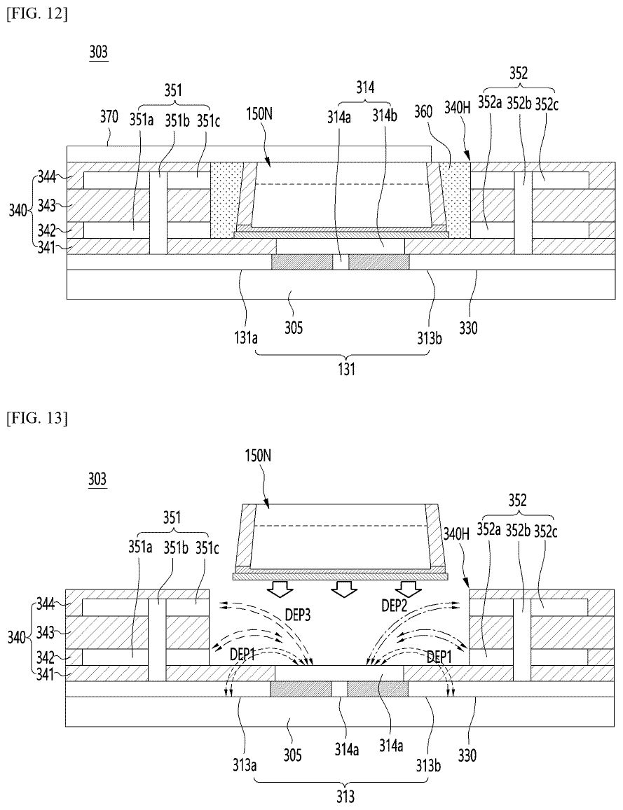

Next, FIG. 12 is a cross-sectional view of a display device (303) having a semiconductor light emitting device according to a third embodiment, and FIG. 13 is a drawing explaining the technical features of the third embodiment illustrated in FIG. 12.

The third embodiment may adopt the technical features of the first or second embodiment, and the following description will focus on the main features of the third embodiment.

The third embodiment may include a third assembly electrode (313) disposed on a substrate (305) and a fourth assembly electrode (314) disposed on an upper side of the third assembly electrode (313).

In addition, the third embodiment may include a first side assembly electrode (351) or a second side assembly electrode (352) electrically connected to the third assembly electrode (313). At this time, unlike the first and second embodiments, the first side assembly electrode (351) and the second side assembly electrode (352) may be applied with power of the same polarity.

In particular, the third embodiment may include a third assembly electrode (313) spaced apart from each other with a predetermined through-space in the substrate (305) and a fourth assembly electrode (314) spaced above the through-space of the third assembly electrode (313).

The third assembly electrode (313) may include a third-first assembly electrode (313a) and a third-second assembly electrode (313b) spaced apart from each other with the through-space. The third-first assembly electrode (313a) and the third-second assembly electrode (313b) may be physically and electrically connected.

The fourth assembly electrode (314) may include a fourth-first assembly electrode (314a) spaced within the through-space of the third assembly electrode (313) and a fourth-second assembly electrode (314a) extending upward from the fourth-first assembly electrode (314a) and spaced above the through-space. It may include an electrode (314b).

The fourth-first assembly electrode (314a) may be disposed at the same height as the third assembly electrode (313), and the fourth-second assembly electrode (314b) may be disposed at a higher position than the third assembly electrode (313).

In the embodiment, the fourth assembly electrode (314) may be electrically connected to the semiconductor light emitting device (150N), and there is a technical effect that a separate side wiring may be omitted.

The fourth assembly electrode (314) may function as an assembly electrode during the assembly stage, and there is a technical effect that it may function as a panel pixel electrode in the panel after assembly.

Next, the technical features of the fourth embodiment will be described in more detail with reference to FIG. 13.

When AC power is applied, a first DEP force (DEP1) is formed between the third assembly electrode (313) and the fourth assembly electrode (314), which can generate a strong DEP fixing force at the lower side of the assembly hole (340H).

In particular, in the third embodiment, the third assembly electrode (313) may include a third-first assembly electrode (313a) and a third-second assembly electrode (313b) that are spaced apart from each other by the through-space.

In addition, the fourth assembly electrode (314) may include a fourth-first assembly electrode (314a) that is positioned within the through-space of the third assembly electrode (313) and a fourth-second assembly electrode (314b) that extends upward from the fourth-first assembly electrode (314a) and is positioned above the through-space.

According to the third embodiment, the third assembly electrode (313) and the fourth assembly electrode (314) are disposed very close together while being spatially separated from each other, thereby forming a uniform and very strong DEP force. Accordingly, the third embodiment can form a uniform and strong first DEP force (DEP1) between the third assembly electrode (313) and the fourth assembly electrode (314), thereby generating a strong DEP fixing force at the lower side of the assembly hole (340H).

Next, in the third embodiment, the fourth-second assembly electrode (314b) can be disposed at a higher position than the third assembly electrode (313) while being disposed close to the first side assembly electrode (351) and the second side assembly electrode (352).

In the third embodiment, a strong second DEP force (DEP2) can be formed between the fourth-second assembly electrode (314b) and the second side assembly electrode (352), and a strong third DEP force (DEP3) can be formed between the fourth-second assembly electrode (314b) and the first side assembly electrode (351).

Accordingly, according to the third embodiment, a second DEP force (DEP2) can be generated between the fourth assembly electrode (314) and the second side assembly electrode (352), and a third DEP force (DEP3) can be generated between the fourth assembly electrode (314) and the first side assembly electrode (351). Therefore, according to the fourth embodiment, there is a special technical effect of being able to generate a strong DEP force that is uniform from the bottom to the top of the assembly hole (340H).

Accordingly, according to the embodiment, by including the first side assembly electrode (351) or the second side assembly electrode (352) electrically connected to the third assembly electrode (313), a second DEP force (DEP2) can be generated between the fourth assembly electrode (314) and the second side assembly electrode (352), and a third DEP force (DEP3) can be generated between the fourth assembly electrode (314) and the first side assembly electrode (351). Therefore, according to the fourth embodiment, since a strong DEP force can be generated uniformly from the lower side to the upper side of the assembly hole (340H), there is a technical effect of significantly improving the assembly rate and assembly speed.

In addition, there is a technical effect of stably fixing the semiconductor light emitting device (150N) assembled in the assembly hole without being detached by the magnetic force of the magnet by the strong first DEP force (DEP1) between the third assembly electrode (313) and the fourth assembly electrode (314) in the assembly hole.

The detailed description above should not be construed as restrictive in all respects but should be considered illustrative. The scope of the embodiments should be determined by a reasonable interpretation of the appended claims, and all changes within the equivalent scope of the embodiments are included in the scope of the embodiments.

### INDUSTRIAL APPLICABILITY

The embodiments can be adopted in the field of displays that display images or information.

The embodiments can be adopted in the field of displays that display images or information using semiconductor light emitting devices.

The embodiments can be adopted in the field of displays that display images or information using micro-level or nano-level semiconductor light emitting devices.

1. An assembly substrate structure of a semiconductor light emitting device for a display pixel, comprising:
a first assembly electrode and a second assembly electrode disposed to be spaced apart from each other on a substrate;
an assembly partition wall including a predetermined assembly hole and disposed on the first and second assembly electrodes; and
a first side assembly electrode or a second side assembly electrode electrically connected to the first electrode or the second assembly electrode, respectively,
wherein the first side assembly electrode comprises a first-first horizontal electrode, a first-second horizontal electrode, and a first bridge wiring connecting the first-first horizontal electrode and the first-second horizontal electrode.

2. (canceled)

3. An assembly substrate structure of a semiconductor light emitting device for a display pixel, comprising:
a first assembly electrode and a second assembly electrode disposed to be spaced apart from each other on a substrate;
an assembly partition wall including a predetermined assembly hole and disposed on the first and second assembly electrodes; and
a first side assembly electrode or a second side assembly electrode electrically connected to the first electrode or the second assembly electrode, respectively,
wherein the second side assembly electrode comprises a second-first horizontal electrode, a second-second horizontal electrode, and a second bridge wiring vertically connecting the second-first horizontal electrode and the second-second horizontal electrode.

4. An assembly substrate structure of a semiconductor light emitting device for a display pixel, comprising:
a first assembly electrode and a second assembly electrode disposed to be spaced apart from each other on a substrate;
an assembly partition wall including a predetermined assembly hole and disposed on the first and second assembly electrodes;
a first side assembly electrode or a second side assembly electrode electrically connected to the first electrode or the second assembly electrode, respectively; and
a side wiring electrically connected to the first assembly electrode or the second assembly electrode.

5. The assembly substrate structure of the semiconductor light emitting device for the display pixel according to claim 4, wherein an upper end of the side wiring is disposed higher than that of the first side assembly electrode or the second side assembly electrode.

6. An assembly substrate structure of a semiconductor light emitting device for a display pixel, comprising:
a first assembly electrode and a second assembly electrode disposed to be spaced apart from each other on a substrate;
an assembly partition wall including a predetermined assembly hole and disposed on the first and second assembly electrodes;
a first side assembly electrode or a second side assembly electrode electrically connected to the first electrode or the second assembly electrode, respectively; and
a light-transmitting first panel wiring disposed on an upper side of the first side assembly electrode or an upper side of the second side assembly electrode and electrically connected thereto.

7. The assembly substrate structure of the semiconductor light emitting device for the display pixel according to claim 6, wherein the light-transmitting first panel wiring comprises a first-first panel electrode electrically connected to the first side assembly electrode or the second side assembly electrode, and a first-second panel electrode electrically connected to the first-first panel electrode.

8. An assembly substrate structure of a semiconductor light emitting device for a display pixel, comprising:
a third assembly electrode disposed on a substrate;
a fourth assembly electrode disposed on an upper side of the third assembly electrode;
an assembly partition wall including a predetermined assembly hole and disposed on the third and fourth assembly electrodes; and
a first side assembly electrode or a second side assembly electrode electrically connected to the first assembly electrode, respectively,
wherein the first side assembly electrode comprises a first-first horizontal electrode, a first-second horizontal electrode, and a first bridge wiring connecting the first-first horizontal electrode and the first-second horizontal electrode.

9. (canceled)

10. The assembly substrate structure of the semiconductor light emitting device for the display pixel according to claim 8, wherein the third assembly electrode is disposed spaced apart from each other with a predetermined through-space in the substrate, and
wherein the fourth assembly electrode is disposed on an upper side of the through-space of the third assembly electrode.

11. The assembly substrate structure of the semiconductor light emitting device for the display pixel according to claim 10, wherein the third assembly electrode includes a third-first assembly electrode and a third-second assembly electrode that are disposed spaced apart from each other with the through-space.

12. The assembly substrate structure of the semiconductor light emitting device for the display pixel according to claim 11, wherein the fourth assembly electrode comprises a fourth-first assembly electrode disposed within the through-space of the third assembly electrode, and a fourth-second assembly electrode to extend upward from the fourth-first assembly electrode and disposed above the through-space.

13. The assembly substrate structure of the semiconductor light emitting device for the display pixel according to claim 12, wherein the fourth-first assembly electrode is disposed at the same height as the third assembly electrode, and
wherein the fourth-second assembly electrode is disposed at a higher position than the third assembly electrode.

14. A display device including the assembly substrate structure of the semiconductor light emitting device for the display pixel according to claim 1.

15. A display device including the assembly substrate structure of the semiconductor light emitting device for the display pixel according to claim 3.

16. A display device including the assembly substrate structure of the semiconductor light emitting device for the display pixel according to claim 4.

17. A display device including the assembly substrate structure of the semiconductor light emitting device for the display pixel according to claim 6.

18. A display device including the assembly substrate structure of the semiconductor light emitting device for the display pixel according to claim 8.
